(19) United States
(12) Patent Application Publication
(10) Pub. No.: US 2008/0259571 A1
(43) Pub. Date: Oct. 23, 2008

(54) Semiconductor device used for a rectifier of a vehicle alternator

(75) Inventor: Shigekazu Kataoka, Aichi-gun (JP)

Correspondence Address: OLIFF & BERRIDGE, PLC, P.O. BOX 320850, ALEXANDRIA, VA, 22320-4850, US

(73) Assignee: DENSO CORPORATION, Kariya-City (JP)

(21) Appl. No.: 12/081,608

(22) Filed: Apr. 17, 2008

(30) Foreign Application Priority Data
Apr. 18, 2007 (JP) 2007-109136

(51) Int. Cl. H05K 7/20

(52) U.S. Cl. 361/714

(57) ABSTRACT

A semiconductor device includes a semiconductor chip, a metal disc portion, a lead, and a sealing material. The semiconductor chip has surfaces both serve as primary electrode surfaces. The metal disc portion is secured to an external cooling metal body. One primary electrode surface of the semiconductor chip is soldered to the disc portion. The lead has a head portion at an end thereof and the head portion is soldered to the other primary electrode surface of the semiconductor chip. The sealing material seals at least a side face of the semiconductor chip and two soldered portions of the disc portion and the head portion. The disc portion is provided with projections on a surface opposite to the surface to which the semiconductor chip is soldered.

### CROSS-REFERENCE TO RELATED APPLICATION

This application is based on and claims the benefit of priority from earlier Japanese Patent Application No. 2007-109136 filed Apr. 18, 2007, the description of which is incorporated herein by reference.

### BACKGROUND OF THE INVENTION

1. Technical field of the Invention

The present invention relates to a semiconductor device used, for example, for a rectifier of a vehicle alternator loaded on a passenger car or a truck.

2. Background Art

Vehicle alternators generate power using motive power transmitted from an engine, to charge a battery, ignite an engine, and supply power to a lighting system or various other electrical parts. In order to maintain or enhance market competitiveness, vehicle alternators have important issues of reducing size and weight, increasing output, reducing cost and enhancing durability. For example, a large current passes through a rectifier element of each of semiconductor devices contained in a rectifier and thus the heat generated by the semiconductor chip is required to be radiated. To this end, semiconductor devices have been attached to the cooling fins using press fitting or soldering process. Such a semiconductor device is generally made up of a disc, a rectifier element and a lead, and is structured by soldering these components, followed by sealing using a sealing material made of silicon rubber or resin. Some measures have been taken for the heat generation of the rectifier elements of the semiconductor devices by, for example, radiating heat toward cooling fins via the discs, or by fanning the semiconductor devices using cooling fans in the vehicle alternator.

With the recent trend of attaining high power in vehicle alternators and downsizing engine rooms, the operating temperature of the semiconductor devices has been increasingly raised. For example, use of semiconductor devices of a rectifier in high temperature may reduce the thermal fatigue life of the solder used for the semiconductor devices. Meanwhile, increase of cooling air is not easy and, even when realized, may increase the fan sound.

Conventional art well known for efficiently cooling semiconductor devices used for a rectifier is disclosed, for example, in Japanese Patent Laid-Open No. 2002-119028. This literature discloses a structure for enhancing cooling performance by interposing a thermal conductive material between each disc and a cooling fin.

In the structure disclosed in this literature, the interposition of the thermal conductive material between each disc of a semiconductor device and a cooling fin, has accompanied the change of the structure of the cooling fin. This has also accompanied the addition and change of the processes for adding the thermal conductive material, for example. Thus, the interposition of the thermal conductive material has raised a problem of cost increase.

### SUMMARY OF THE INVENTION

The present invention has been made in light of the problem mentioned above, and has as its object to provide a semiconductor device which is able to enhance the cooling performance of the rectifier and suppress cost increase.

In order to solve the problem mentioned above, the semiconductor device of the present invention comprises: a semiconductor chip whose surfaces both serve as primary electrode surfaces; a metal disc portion which is secured to an external cooling metal body and to which one primary electrode surface of the semiconductor chip is soldered; a lead having a head portion at an end thereof, the head portion being soldered to the other primary electrode surface of the semiconductor chip; and a sealing material for sealing at least a side face of the semiconductor chip and two soldered portions of the disc portion and the head portion, wherein the disc portion is provided with projections on a surface opposite to the surface to which the semiconductor chip is soldered.

Thus, enhancement can be attained in the radiation performance of the disc portion by forming the projections in the surface of the disc portion for the increase of the radiation area. As a result, the cooling performance of each of the semiconductor devices and the rectifier using the semiconductor devices can also be enhanced, while the cost increase can be suppressed.

It is preferred that the disc portion is provided with a recess having a bottom face to which the semiconductor chip is soldered, an outer peripheral surface of the recess being fitted to an inner peripheral surface of a fixing hole formed in the cooling metal body, the projections being exposed outside the fixing hole. In particular, it is preferred that the projections are projected out of an aperture plane of the fixing hole.

By laying the projections open to the surrounding space, reliable enhancement can be attained in the radiation performance of each disc portion to which the semiconductor chip is soldered.

It is preferred that the projections have linear shapes which are parallel to each other. Alternatively, it is preferred that the projections are arranged in a latticed manner with a predetermined interval there between.

Thus, the flow of the cooling air along the projections can be prevented from being blocked to further enhance the cooling performance.

Also, it is preferred that the disc portion is formed by press molding a metal material, and the projections are integrally formed with the disc portion as a part thereof.

Thus, the integral formation can prevent the increase of the number of parts, and may require no addition or change of processes in manufacturing the semiconductor device. As a result, cost increase can be suppressed, which would have otherwise accompanied the enhancement of the cooling performance.

### BRIEF DESCRIPTION OF THE DRAWINGS

In the accompanying drawings,

FIG. 1 is a cross sectional view illustrating a general configuration of a vehicle alternator according to an embodiment of the present invention;

FIG. 2 is a plan view illustrating a detailed structure of a rectifier;

FIG. 3 is an enlarged cross sectional view taken along a line III-III of FIG. 2;

FIG. 4 is an enlarged cross sectional view of a positive rectifier element;

FIG. 5 is a plan view illustrating a configuration of protrusions formed in an end face of a disc portion; and

FIG. 6 illustrates a modification of the configuration of the protrusions.

### DETAILED DESCRIPTION OF THE PREFERRED EMBODIMENTS

With reference to the accompanying drawings, hereinafter will be described a vehicle alternator according to an embodiment to which semiconductor devices of the present invention are applied.

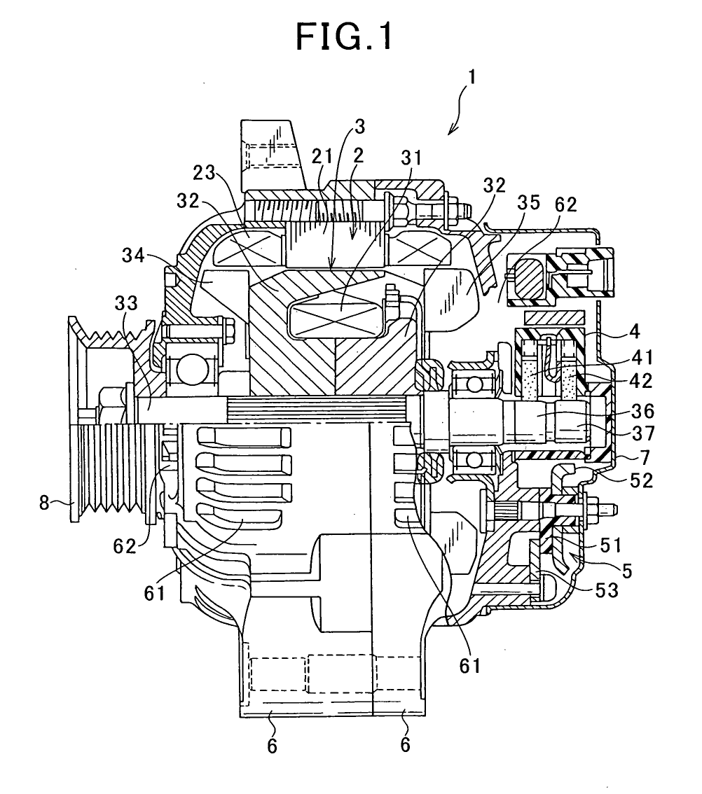

FIG. 1 is a cross sectional view illustrating a general configuration of the vehicle alternator according to the present embodiment.

A vehicle alternator 1 illustrated in FIG. 1 is configured by a stator 2, a rotor 3, a brushing device 4, a rectifier 5, a frame 6, a rear cover 7 and a pulley 8.

The stator 2 includes a stator core 21 and a three-phase stator winding 23 which is wound about a plurality of slots formed at the stator core 21, so that turns of the winding has a predetermined interval therebetween. The rotor 3 has a structure in which a field winding 31 made up of a cylindrically and concentrically wound insulated copper wire is sandwiched, from both sides thereof, by halves of a pole core 32 each having six claws, with a rotary shaft 33 being passed therethrough. An axial cooling fan 34 is attached, by welding or the like, to an end face of the front-half pole core 32 to axially and radially discharge cooling air sucked from the front side. Similarly, a centrifugal cooling fan 35 is attached, by welding or the like, to an end face of the rear-half pole core 32 to radially discharge cooling air sucked from the rear side.

The brushing device 4 has a function of passing excitation current from the rectifier 5 to the field winding 31 of the rotor 3, and is provided with brushes 41 and 42 for pressing slip rings 36 and 37, respectively, formed at the rotary shaft 33 of the rotor 3.

The rectifier 5 has a function of obtaining DC output power by rectifying three-phase AC voltage, or output voltage, of the three-phase stator winding 23. The rectifier 5 is configured by: a terminal block 51 having wiring electrodes therein; positive and negative heat sinks 52 and 53 arranged with a predetermined interval therebetween each constituting a part of each semiconductor device; and a plurality of rectifier elements 54 and 55 (described later) which are press fitted to punched holes of the respective heat sinks, each element constituting a part of each semiconductor device.

The stator 2 and the rotor 3 are accommodated in the frame 6 which provides support so that the rotor 3 is rotatable about the rotary shaft 33. The stator 2 is secured to the frame 6, and arranged with a predetermined gap being provided between itself and an outer peripheral side of the pole core 32 of the rotor 3. The frame 6 is provided with: outlet windows 61 for cooling air, defined at a portion opposed to the stator winding 23 projected from an axial end face of the stator core 21; and inlet windows 62 for cooling air, defined at an axial end face of the frame 6.

The rear cover 7 covers and protects the brushing device 4 externally attached to the rear-side frame 6, and also covers and protects the rectifier 5 and an IC regulator, in their entirety.

In the vehicle alternator 1 having the structure described above, the rotor 3 is adapted to rotate in a predetermined direction upon transmission of torque to the pulley 8 from the engine (not shown) via a belt or the like. In this state, external application of excitation current to the field winding 31 of the rotor 3 can excite the claws of each half of the pole core 32 to have the stator winding 23 generated three-phase AC voltage. As a result, DC output power can be retrieved from an output terminal of the rectifier 5.

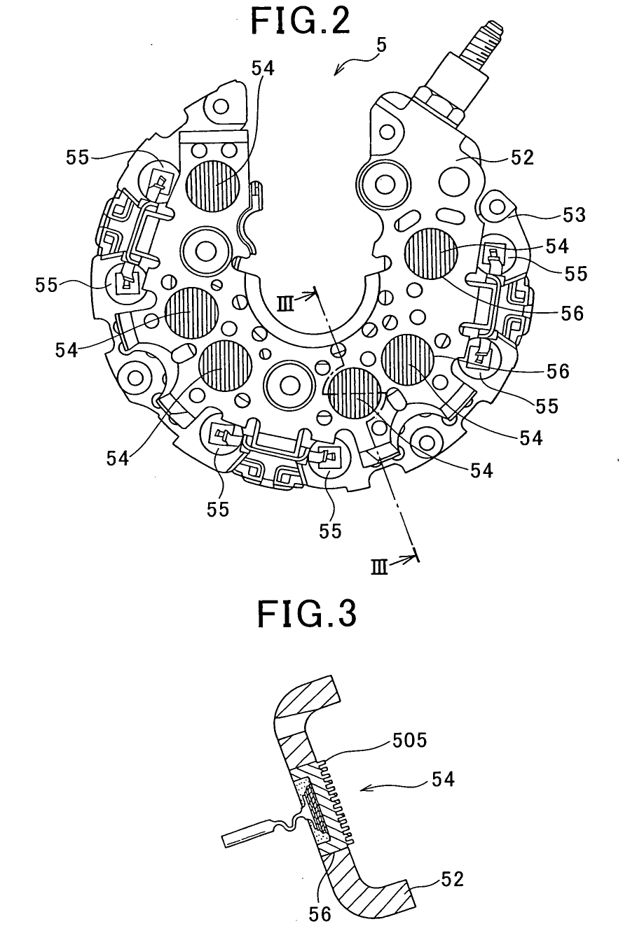

Hereinafter is described the details of the rectifier 5. FIG. 2 is a plan view illustrating a detailed structure of the rectifier 5. The following description is chiefly focused on the positive rectifier elements 54, each constituting a part of each semiconductor device, which element is press fitted to the positive heat sink 52. Since the similar description can be applied to the negative heat sink 53 and the negative rectifier elements 55, detailed description is omitted.

The rectifier 5 has a cooling metal body made up of the positive and negative heat sinks 52 and 53. Six fixing holes 56 are formed in the positive heat sink 52, with the positive rectifier elements 54 being press fitted and secured to the respective fixing holes 56. Specifically, an outer peripheral surface (outer peripheral surface of a disc portion 500 described later) of each positive rectifier element 54 is fitted to an inner peripheral surface of each fixing hole 56 to secure the positive rectifier element 54 to the hole. Use of press fitting process for securing each positive rectifier elements 54 to the positive heat sink 52 can reduce the number of processes and cost, comparing with the case where soldering process is used for the securing.

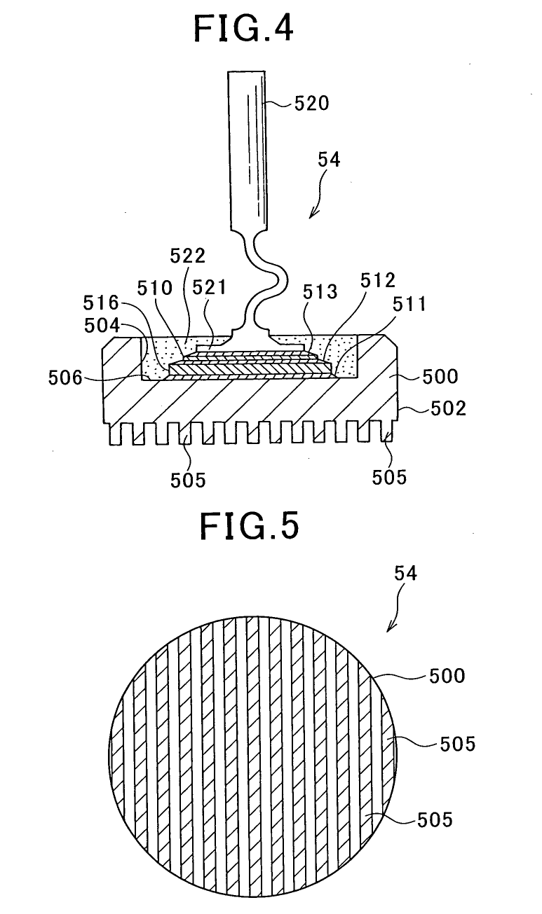

FIG. 3 is an enlarged view taken along a line III-III of FIG. 2, illustrating a cross-sectional configuration of the positive rectifier element 54 and the positive heat sink 52. FIG. 4 is an enlarged view of the positive rectifier element 54. As shown in FIG. 4, the positive rectifier element 54 is made up of a disc portion 500, a semiconductor chip 510, a buffer plate 516, and a lead 520. The semiconductor chip 510 has a circular shape, whose surfaces both serve as primary electrode surfaces. The disc portion 500 is used for attaining fixation to the fixing hole 56 of the positive heat sink 52 and for soldering one primary electrode surface of the semiconductor chip 510. The disc portion 500 has a cylindrical shape, with a knurl 502 being formed in the outer periphery and a recess 504 being formed in one end face. A bottom face of the recess 504 serves as a joint surface for soldering the semiconductor chip 510 thereto. The lead 520 has a head portion 521 at an end thereof, which is soldered to the other primary electrode surface of the semiconductor chip 510.

The positive rectifier element 54 is structured by soldering the buffer plate 516 onto the joint surface 506 of the disc portion 500 using solder 511, soldering the semiconductor chip 510 onto the top of the buffer plate 516 using solder 521, and soldering the head portion 521 of the lead 520 onto the top of the semiconductor chip 510 using solder 513. A sealing material 522 made of silicon rubber or resin is filled to seal the side face of the semiconductor chip 510, as well as the soldered portions between the disc portion 500, the buffer plate 516, the semiconductor chip 510 and the head portion 521, or preferably, to entirely cover the recess 504 of the disc portion 500. The buffer plate 516 chiefly plays a roll of preventing an excessive stress that would otherwise be applied to the solder layer between the semiconductor chip 510 and the disc portion 500. The excessive stress is caused by the difference in the thermal expansion between the semiconductor chip 510 and the disc portion 500. Therefore, from the viewpoint of enhancing the cooling performance, the buffer plate 516 may be omitted.

Meanwhile, projections 505 are formed in the other end face (the face opposite to the face where the semiconductor chip 510 is soldered) of the disc portion 500 described above. The projections 505 are formed so as to be exposed outside the fixing hole 56 of the positive heat sink 52. Specifically, as shown in FIG. 3, the projections 505 are formed in the end face of the disc portion 500, so as to be projected out of one surface of the positive heat sink 52 that defines the aperture plane of the fixing hole 56.

FIG. 5 is a plan view illustrating a configuration of the projections 505 formed in the end face of the disc portion 500. It should be appreciated that, in FIG. 5, the projections 505 are hatched for distinction from the recessed portions between the adjacent projections 505. In the example shown in FIG. 5, the projections 505 have linear shapes, which are parallel to each other. The disc portion 500 in the present embodiment is formed by press molding a metal material, with the integration of the projections 505 as a part of the disc portion 500.

As described above, the positive rectifier element 54 constituting a part of each semiconductor device used in the rectifier 5 of the alternator 1 of the present embodiment, can impart an enhanced radiation performance to the disc portion 500 by increasing the radiation area with the formation of the projections 505 in the surface of the disc portion 500. Thus, the cooling performance of each of the positive rectifier elements 54, and therefore of the rectifier 5 using the elements, can be enhanced, while the cost increase can be suppressed.

The projections 505 formed in the disc portion 500 are projected out of the aperture plane of the fixing hole 56, that is, projected out of the surface of the positive heat sink 52. Thus, by laying the projections 505 open to the surrounding space, reliable enhancement can be attained in the radiation performance of the disc portion 500 to which the semiconductor chip 510 is soldered.

Also, owing to the linear shapes of the projections 505 which are parallel to each other, the flow of the cooling air along the projections 505 can be prevented from being blocked to further enhance the cooling performance. In addition, since the disc portion 500 is formed by press molding a metal material to integrally form the projections 505 as a part of the disc portion 500, increase of the number of parts can be prevented. At the same time, this integral formation may require no addition or change of processes in manufacturing the positive rectifier elements 54. As a result, the cost increase can be suppressed, which would have otherwise accompanied the enhancement of the cooling performance.

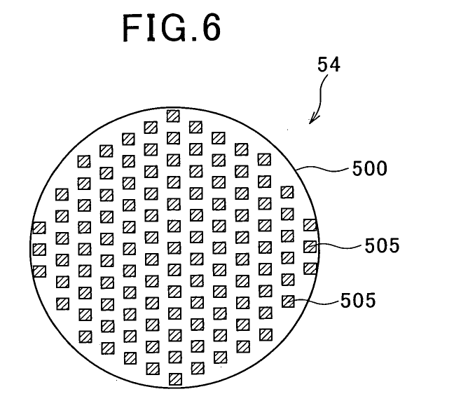

The present invention is not intended to be limited to the embodiment described above, but may be variously modified without departing from the spirit of the present invention. For example, the projections 505 in the embodiment described above, which have been formed in the surface of the disc portion 500, have had linear shapes and have been parallel to each other. Alternative to this, the projections 505 may have other shapes, such as, a latticed shape, as shown in FIG. 6, with a predetermined interval therebetween, or may have a concentric circular shape.

What is claimed is:

1. A semiconductor device comprising:
a semiconductor chip whose surfaces both serve as primary electrode surfaces;
a metal disc portion which is secured to an external cooling metal body and to which one primary electrode surface of the semiconductor chip is soldered;
a lead having a head portion at an end thereof, the head portion being soldered to the other primary electrode surface of the semiconductor chip; and
a sealing material for sealing at least a side face of the semiconductor chip and two soldered portions of the disc portion and the head portion,
wherein the disc portion is provided with projections on a surface opposite to the surface to which the semiconductor chip is soldered.

2. The semiconductor device according to claim 1,
wherein the disc portion is provided with a recess having a bottom face to which the semiconductor chip is soldered, an outer peripheral surface of the recess being fitted to an inner peripheral surface of a fixing hole formed in the cooling metal body, the projections being exposed outside the fixing hole.

3. The semiconductor device according to claim 2,
wherein the projections are projected out of an aperture plane of the fixing hole.

4. The semiconductor device according to claim 1,
wherein the projections have linear shapes which are parallel to each other.

5. The semiconductor device according to claim 1,
wherein the projections are arranged in a latticed manner with a predetermined interval therebetween.

6. The semiconductor device according to claim 1,
wherein the disc portion is formed by press molding a metal material, and the projections are integrally formed with the disc portion as a part thereof.

7. The semiconductor device according to claim 1,
wherein the semiconductor is a rectifier which is mounted on a vehicle and which rectifies an AC (alternating current) output from a generator mounted on the vehicle.

8. The semiconductor device according to claim 2,
wherein the projections have linear shapes which are parallel to each other.

9. The semiconductor device according to claim 2,
wherein the projections are arranged in a latticed manner with a predetermined interval therebetween.

10. The semiconductor device according to claim 2,
wherein the disc portion is formed by press molding a metal material, and the projections are integrally formed with the disc portion as a part thereof.

11. The semiconductor device according to claim 2, wherein the semiconductor is a rectifier which is mounted on a vehicle and which rectifies an AC (alternating current) output from a generator mounted on the vehicle.

12. The semiconductor device according to claim 3,
wherein the projections have linear shapes which are parallel to each other.

13. The semiconductor device according to claim 3,
wherein the projections are arranged in a latticed manner with a predetermined interval therebetween.

14. The semiconductor device according to claim 3,
wherein the disc portion is formed by press molding a metal material, and the projections are integrally formed with the disc portion as a part thereof.

15. The semiconductor device according to claim 3,
wherein the semiconductor is a rectifier which is mounted on a vehicle and which rectifies an AC (alternating current) output from a generator mounted on the vehicle.
